(19) United States
(12) Patent Application Publication
(10) Pub. No.: US 2025/0391672 A1
(43) Pub. Date: Dec. 25, 2025

(54) METHODS AND APPARATUS FOR GAS DISTRIBUTION

(71) Applicant: ASM IP Holding B.V., Almere (NL)

(72) Inventors: Kyle Fondurulia, Phoenix, AZ (US); Ankit Kimtee, Phoenix, AZ (US)

(21) Appl. No.: 19/241,640

(22) Filed: Jun. 18, 2025

Related U.S. Application Data
(60) Provisional application No. 63/663,596, filed on Jun. 24, 2024.

(51) Int. Cl. H01L 21/67

(52) U.S. Cl. CPC H01L 21/67017

(57) ABSTRACT

Various embodiments of the present technology may provide a showerhead plate having a first surface and an opposing second surface, a circular cutout in the second surface, wherein the cutout comprises an opening having a first diameter at the second surface and a groove that projects radially outwards from a vertical axis and forms a second diameter, wherein the second diameter is larger than the first diameter, and a protrusion disposed between the first and second surfaces that projects inwards toward the axis, wherein the protrusion forms the groove.

### CROSS-REFERENCE TO RELATED APPLICATIONS

This application is a nonprovisional of, and claims priority to and the benefit of, U.S. Provisional Patent Application No. 63/663,596, filed Jun. 24, 2024 and entitled “METHODS AND APPARATUS FOR GAS DISTRIBUTION,” which is hereby incorporated by reference herein.

### FIELD OF INVENTION

The present disclosure generally relates to a method and apparatus for gas distribution. More particularly, the present disclosure relates to a showerhead having an integrated flow feature to provide improved air flow.

### BACKGROUND OF THE TECHNOLOGY

Reaction chambers used in semiconductor manufacturing typically utilize a gas distribution system to deliver chemistry to a wafer in a reaction space and to remove vapor from the reaction space. Conventional gas distribution systems may produce undesired turbulent air flow in the exhaust stream near the wafer.

### SUMMARY OF THE INVENTION

Various embodiments of the present technology may provide a showerhead plate having a first surface and an opposing second surface, a circular cutout in the second surface, wherein the cutout comprises an opening having a first diameter at the second surface and a groove that projects radially outwards from a vertical axis and forms a second diameter, wherein the second diameter is larger than the first diameter, and a protrusion disposed between the first and second surfaces that projects inwards toward the axis, wherein the protrusion forms the groove.

According to one aspect, an apparatus, comprises: a first surface and an opposing second surface; a circular cutout in the second surface, wherein the cutout comprises an opening having a first diameter at the second surface and a groove that projects radially outwards from a vertical axis and forms a second diameter, wherein the second diameter is larger than the first diameter; and a protrusion disposed between the first and second surfaces that projects inwards toward the axis, wherein the protrusion forms at least a portion of the groove.

In one embodiment, the groove comprises a depth in a range of 20 mm to 45 mm.

In one embodiment, the apparatus further comprises a plurality of first through-holes extending from the first surface to the groove.

In one embodiment, the plurality of first through-holes are arranged at an outer-most dimension of the groove.

In one embodiment, the plurality of first through-holes is fluidly coupled to the groove.

In one embodiment, the groove is angled upwards toward the first surface.

In one embodiment, the protrusion comprises a downward-facing, horizontal surface.

In one embodiment, the first diameter is in the range of 417 mm to 370 mm and the second diameter is in the range of 400 mm to 450 mm.

In another aspect, an apparatus, comprises: a gas distribution plate comprising an inlet plenum and an exhaust plenum; and a showerhead plate comprising: a first surface in direct contact with the gas distribution plate and an opposing second surface; a circular cutout in the second surface, wherein the cutout comprises an opening having a first diameter at the second surface and a groove that projects radially outwards from a vertical axis and forms a second diameter, wherein the second diameter is larger than the first diameter; a circular protrusion disposed between the first and second surfaces that projects inwards toward the axis, wherein the protrusion forms the groove; a plurality of first through-holes extending from the first surface to the groove and in fluid communication with the exhaust plenum; and a plurality of second through-holes extending from the first surface to a surface of the cutout and in fluid communication with the inlet plenum.

In one embodiment, the groove is angled upwards toward the first surface.

In one embodiment, the plurality of first through-holes are arranged at an outer-most dimension of the groove.

In one embodiment, the groove comprises a depth in a range of 20 mm to 45 mm.

In one embodiment, the protrusion comprises a downward-facing, horizontal surface configured to make contact with a susceptor.

In one embodiment, the first diameter is in the range of 417 mm to 370 mm.

In one embodiment, the second diameter is in the range of 400 mm to 450 mm.

In one embodiment, the apparatus further comprises a susceptor configured to engage with the opening of the cutout and the protrusion.

In yet another aspect, an apparatus comprises: a first horizontal surface and an opposing second horizonal surface; a circular cutout in the second surface, wherein the cutout comprises an opening having a first diameter at the second surface and a groove that projects radially outwards from a vertical axis and forms a second diameter, wherein the second diameter is larger than the first diameter; a circular protrusion disposed between the first and second surfaces that projects inwards toward the axis, wherein the protrusion forms the groove; a plurality of first through-holes extending from the first surface to a surface of the groove, wherein the plurality of through-holes are fluidly coupled to the groove; and a plurality of second through-holes extending from the first surface to a surface of the cutout and fluidly coupled to the cutout.

In one embodiment, the first diameter is in the range of 417 mm to 370 mm and the groove comprises a depth in a range of 20 mm to 45 mm.

In one embodiment, the second diameter is in the range of 400 mm to 450 mm and the groove comprises a depth in a range of 20 mm to 45 mm.

In one embodiment, the groove is angled upwards toward the first surface.

### BRIEF DESCRIPTION OF THE DRAWING FIGURES

A more complete understanding of the present technology may be derived by referring to the detailed description when considered in connection with the following illustrative figures. In the following figures, like reference numbers refer to similar elements and steps throughout the figures.

FIG. 1 representatively illustrates a system in accordance with embodiments of the present technology;

FIG. 2 is a cross-sectional view of a gas distribution system in accordance with embodiments of the present technology;

FIG. 3 is a partial cross-sectional view of the gas distribution system in accordance with embodiments of the present technology;

FIG. 4 is a top perspective view of a showerhead plate in accordance with embodiments of the present technology;

FIG. 5 is a cross-sectional view of the showerhead plate in accordance with embodiments of the present technology; and

FIG. 6 is a bottom view of the showerhead plate in accordance with embodiments of the present technology.

### DETAILED DESCRIPTION OF EXEMPLARY EMBODIMENTS

The present technology may be described in terms of functional block components and various processing steps. Such functional blocks may be realized by any number of components configured to perform the specified functions and achieve the various results. For example, the present technology may employ various gas lines, valves, controllers, reaction chambers, vessels, susceptors, and temperature sensors.

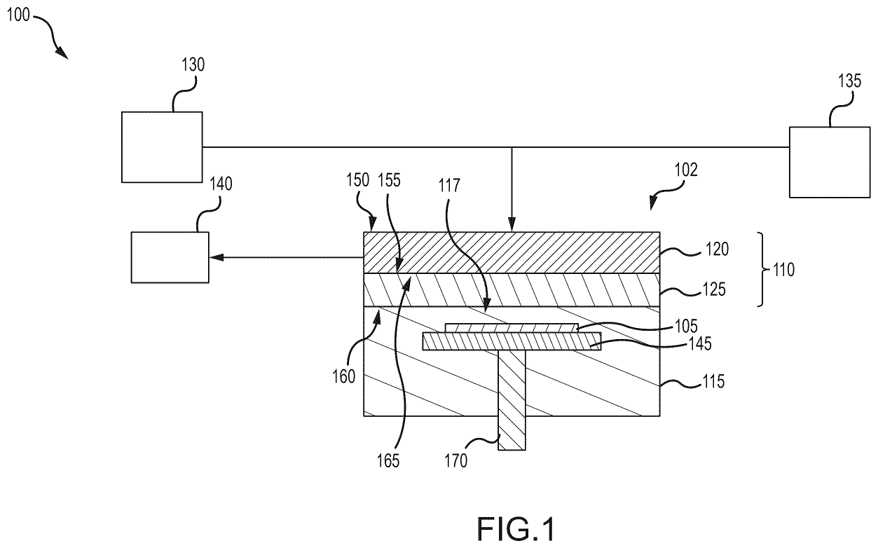

Referring to FIG. 1, an exemplary system 100 may comprise a reactor 102 configured to perform processing on an object to be processed, such as a substrate 105 (e.g., a wafer). For example, the reactor 102 may be configured to perform heating, deposition, etching, polishing, ion implantation, and/or other processing on the object to be processed. In some embodiments, the reactor 102 may be configured to perform a movement function, a vacuum sealing function, and an exhaust function. In some embodiments, the reactor 102 may perform an atomic layer deposition (ALD) process or a chemical vapor deposition (CVD) process.

In an exemplary embodiment, the reactor 102 may comprise a reaction chamber 115 comprising a reaction space 117 above and/or around the substrate 105. For example, the reaction chamber 115 may comprise sidewalls and a bottom coupled to the sidewalls.

In various embodiments, the system 100 may further comprise a substrate mounting unit disposed within the reaction chamber 115 of the reactor 102. The substrate mounting unit may comprise a susceptor 145 for supporting the substrate 105 and a heater (not shown) for heating the substrate 105 supported by the susceptor 145. The heater may be embedded within the susceptor 145. The substrate mounting unit may further comprise a pedestal 170 to support the susceptor 145. For loading/unloading of the substrate 105, the substrate mounting unit may be configured to be vertically movable (up and down) by being connected to a driving unit (not shown). The susceptor 145 may be disposed in or adjacent the reaction space 155. For example, the susceptor 145 may be arranged to position the substrate 150 in the reaction space 155.

In various embodiments, the reactor 102 may further comprise a gas distribution system 110 for delivering a vapor into the reaction chamber 115. In an exemplary embodiment, the gas distribution system 110 is arranged above the susceptor 145. The gas distribution system 110 may comprise a top portion 120 (i.e., a gas channel plate) and a bottom portion 125 (i.e., a showerhead plate). The top and bottom portions 120, 125 may be in direct contact with each other. For example, the top portion 120 may comprise a first surface 150 and an opposite, parallel second surface 165, and the bottom portion 125 may comprise a first surface 155 and an opposing, parallel second surface 160. A surface (e.g., the second surface 165) of the top portion 120 may be direct contact with a surface (e.g., the first surface 155) of the bottom portion 125. In some embodiments, the first and second portions 120, 125 may be coupled together with a fastener, such as a screw or the like.

In various embodiments, the gas distribution system 110 may be arranged adjacent to the reaction chamber 115. For example, the gas distribution system 110 may be disposed on the sidewalls of the reaction chamber 115, opposite from the bottom of the reaction chamber 115. In some embodiments, the gas distribution system 110 may be fastened to the sidewalls, however, in other cases, the gas distribution system 110 may merely rest on the sidewalls of the reaction chamber 115. In various embodiments, the gas distribution system 110 together with the reaction chamber 115 sidewalls form an enclosed space, including the reaction space 155.

In various embodiments, the system 100 may further comprise a vessel 135 configured to contain a chemical (i.e., a precursor). The vessel 135 may be configured to hold a solid or a liquid chemical, and may further be configured to transform the solid or liquid into a vapor. The vessel 135 may be coupled to the gas distribution system 110. For example, the system 100 may further comprise various gas conduits (not shown) and/or valves (not shown) to flow the vapor from the vessel 135 into the gas distribution system 110.

In various embodiments, the system 100 may further comprise an inert gas source 130 configured to contain an inert gas, such as a argon or the like. The inert gas source 130 may be fluidly coupled to the gas distribution system 110 via any number of gas lines/conduits and/or valves.

In an exemplary embodiment, and referring to FIGS. 1-3, the top portion 120 may comprise an inlet plenum 200 configured to receive vapor from the vessel 135 and an exhaust plenum 205 configured to evacuate vapor from the reaction space 117.

The exhaust plenum 205 may comprise an inlet at the second surface 165 and an outlet coupled to an exhaust system 140. For example, gas may flow from the exhaust plenum 205 and into the exhaust system 140. In various embodiments, the exhaust plenum 205 may be arranged concentric with the inlet plenum 200. For example, the exhaust plenum 205 may have a ring shape that surrounds and is larger than the inlet plenum 200.

In various embodiments, the exhaust system 140 may comprise a foreline (not shown) and a pump (e.g., a vacuum pump) (not shown) to facilitate evacuation of gas from the reaction space 117. In various embodiments, the exhaust plenum 205 may be fluidly coupled to the exhaust system 140.

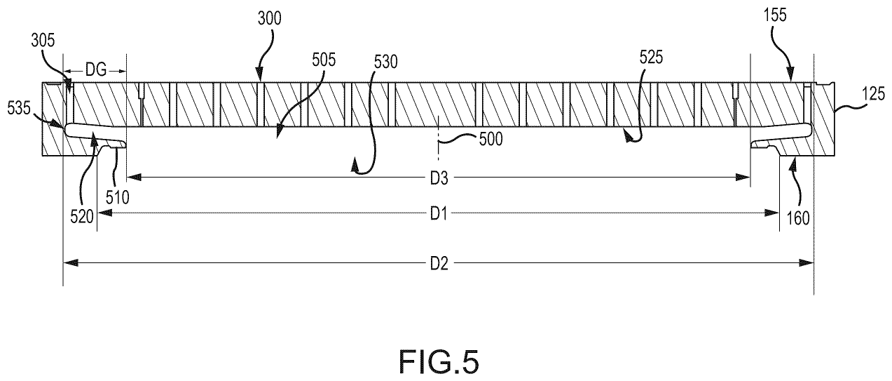

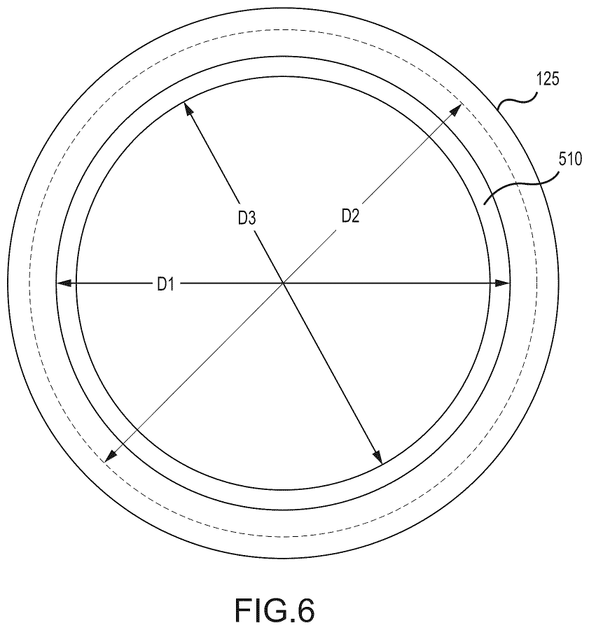

In various embodiments, and referring to FIGS. 5 and 6, the bottom portion 125 may comprise a cutout 505 in the second surface 160. In an exemplary embodiment, the cutout 505 may have comprise a circular opening 530 at the second surface 160 and having a first diameter D1. The cutout 505 may further comprise a groove 520 that projects radially outwards from a vertical axis 500 and forms a second diameter D2. The groove 505 may have an outer edge that forms a circular or arched shape. In various embodiments, the second diameter D2 is larger than the first diameter D1. For example, in various embodiments, the first diameter D1 is in the range of 417 mm to 370 mm, and the second diameter is in the range of 400 mm to 450 mm. The groove 520 may comprise a depth DG in a range of 20 mm to 45 mm. In various embodiments, the groove 520 may be angled upwards toward the first surface 155 of the bottom portion 125. In other cases, the groove 520 may be completely horizontally-oriented.

In various embodiments, the cutout 505 may further comprise a protrusion 510 that extends or otherwise projects radially inwards into the cutout 505 and towards the vertical axis 500 and forms at least a portion of a surface of the groove 520. The protrusion 510 may form a circular shape. In addition, the protrusion 510 may form an opening having a third diameter D3 that is less than the first diameter D1. The protrusion 510 may be arranged between the second surface 160 and the first surface 155. In other words, the protrusion 510 is not flush with the second surface 160.

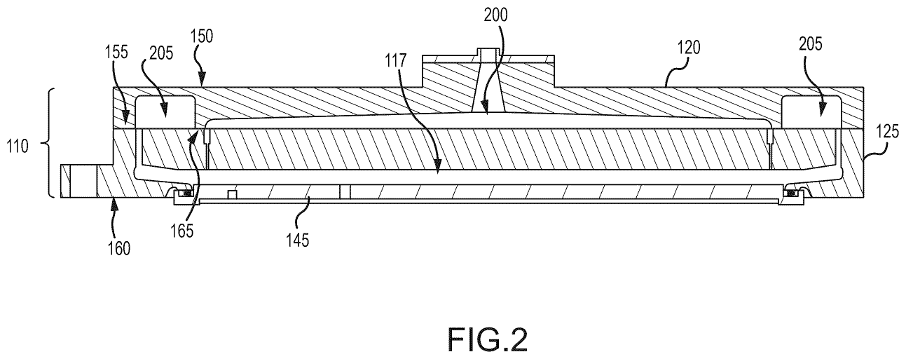

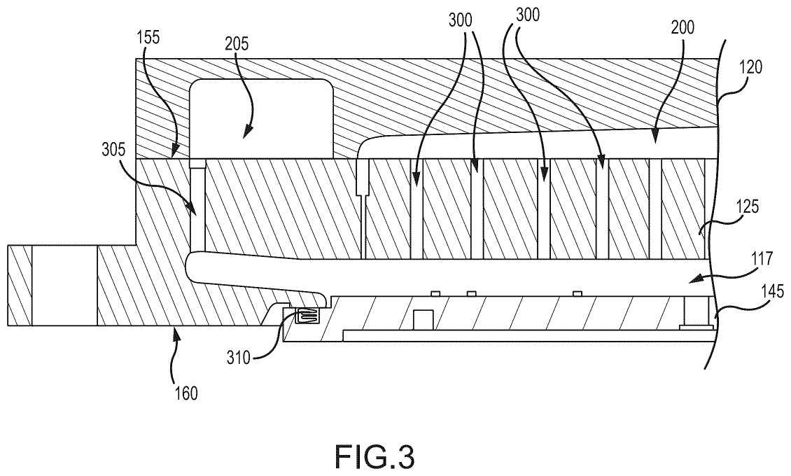

In various embodiments, and referring to FIGS. 2-3, the susceptor 145 may engage with the cutout 505 and the protrusion 510. In particular, the susceptor 145 may be sized to fit within the opening 530 of the cutout 505. In addition, the protrusion 510 may comprise a downward-facing, horizontal surface configured to make contact with an edge of the susceptor 145. In some embodiments, a metal seal 310 may be disposed between the downward-facing surface and the susceptor 145. When the susceptor 145 engages with the cutout 505, the reaction space 117 is formed between the susceptor 145 and a surface 525 of the cutout 505.

In various embodiments, the bottom portion 125 may further comprise a plurality of inlet through-holes 300 that extend through the first surface 155 and the surface 525 of the cutout 505. The plurality of inlet through-holes 300 may contain approximately 1000-1200 through-holes. The plurality of inlet through-holes 300 may be arranged within a central region (also referred to as a showerhead region) of the bottom portion 125. The inlet plenum 200 may be in fluid communication with the plurality of inlet through-holes 300. For example, the vapor that flows into the inlet plenum 200 from the vessel 135 may continue to flow through the plurality of through-holes 300. The plurality of inlet through-holes 300 may also be in fluid communication with the reaction space 117. For example, the vapor may flow through the plurality of inlet through-holes 300 and into the reaction space 117. In an exemplary embodiment, the plurality of inlet through-holes 300 are arranged radially inward from protrusion 510.

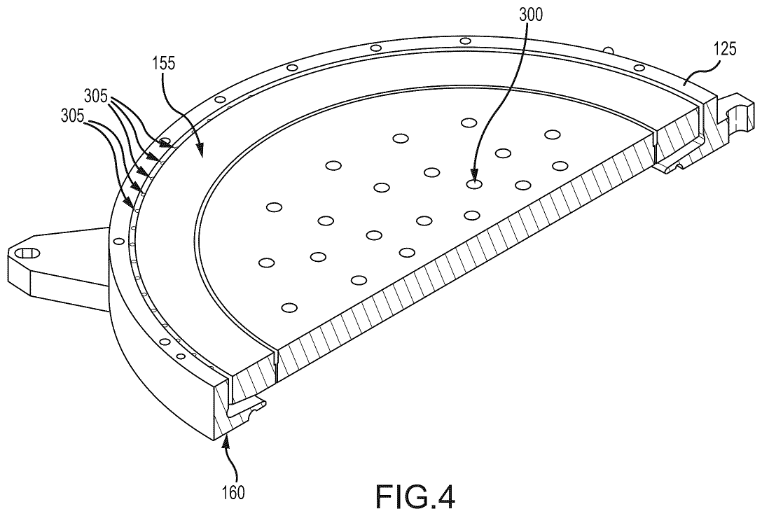

In various embodiments, and referring to FIGS. 3 and 5, the bottom portion 125 may further comprise a plurality of exhaust through-holes 305 (e.g., 20-100 holes, in particular, 65-80 holes) fluidly coupled to the exhaust plenum 205. The plurality of exhaust through-holes 305 may each have a first opening at the first surface 155 of the bottom portion 125 and a second opening at a surface of the groove 520, for example, a top surface of the groove 520. In an exemplary embodiment, the plurality of exhaust through-holes 305 may be arranged at or near an outer-most dimension of the groove 520. For example, the plurality of exhaust through-holes 305 may align with a terminating edge 535 of the groove 520. The plurality of exhaust through-holes 305 may be arranged in a ring pattern (e.g., as illustrated in FIG. 4). In addition, the first openings of the plurality of exhaust through-holes 305 may be positioned to be in fluid communication with the exhaust plenum 205. In particular, the first openings of the plurality of exhaust through-holes 305 may align with the inlet of the exhaust plenum 205. In addition, the plurality of exhaust through-holes 305 may be arranged radially outwards from the plurality of inlet through-holes 300.

In operation, and referring to FIGS. 1-6, the system 100 may be configured to perform atomic layer deposition (ALD), wherein the precursor from the vessel 135 is pulsed into the reaction space 117 via the gas distribution system 110 and then purged using an inert gas, such as argon. For example, during the pulsing step, vapor flows from the vessel 135, into the inlet plenum 200, through the through-holes 300 and into the reaction space 117. During the purging step, the chemical vapor from the pulsing step is evacuated from the reaction space 117 by flowing the inert gas from the inert gas source 130 into the inlet plenum 200, through the through-holes 300. At this time, the exhaust system 140 is utilized and the vapor is able to flow radially outwards from the reaction space 117 and directed by the groove 520 to flow into the exhaust plenum 205 via through-holes 305.

In the foregoing description, the technology has been described with reference to specific exemplary embodiments. The particular implementations shown and described are illustrative of the technology and its best mode and are not intended to otherwise limit the scope of the present technology in any way. Indeed, for the sake of brevity, conventional manufacturing, connection, preparation, and other functional aspects of the method and system may not be described in detail. Furthermore, the connecting lines shown in the various figures are intended to represent exemplary functional relationships and/or steps between the various elements. Many alternative or additional functional relationships or physical connections may be present in a practical system.

The technology has been described with reference to specific exemplary embodiments. Various modifications and changes, however, may be made without departing from the scope of the present technology. The description and figures are to be regarded in an illustrative manner, rather than a restrictive one and all such modifications are intended to be included within the scope of the present technology. Accordingly, the scope of the technology should be determined by the generic embodiments described and their legal equivalents rather than by merely the specific examples described above. For example, the steps recited in any method or process embodiment may be executed in any order, unless otherwise expressly specified, and are not limited to the explicit order presented in the specific examples. Additionally, the components and/or elements recited in any apparatus embodiment may be assembled or otherwise operationally configured in a variety of permutations to produce substantially the same result as the present technology and are accordingly not limited to the specific configuration recited in the specific examples.

Benefits, other advantages and solutions to problems have been described above with regard to particular embodiments. Any benefit, advantage, solution to problems or any element that may cause any particular benefit, advantage or solution to occur or to become more pronounced, however, is not to be construed as a critical, required or essential feature or component.

The terms “comprises”, “comprising”, or any variation thereof, are intended to reference a non-exclusive inclusion, such that a process, method, article, composition or apparatus that comprises a list of elements does not include only those elements recited, but may also include other elements not expressly listed or inherent to such process, method, article, composition or apparatus. Other combinations and/or modifications of the above-described structures, arrangements, applications, proportions, elements, materials or components used in the practice of the present technology, in addition to those not specifically recited, may be varied or otherwise particularly adapted to specific environments, manufacturing specifications, design parameters or other operating requirements without departing from the general principles of the same.

The present technology has been described above with reference to an exemplary embodiment. However, changes and modifications may be made to the exemplary embodiment without departing from the scope of the present technology. These and other changes or modifications are intended to be included within the scope of the present technology, as expressed in the following claims.

What is claimed is:

1. An apparatus, comprising:
a first surface and an opposing second surface;
a circular cutout in the second surface, wherein the cutout comprises an opening having a first diameter at the second surface and a groove that projects radially outwards from a vertical axis and forms a second diameter, wherein the second diameter is larger than the first diameter; and
a protrusion disposed between the first and second surfaces that projects inwards toward the axis, wherein the protrusion forms at least a portion of the groove.

2. The apparatus according to claim 1, wherein the groove comprises a depth in a range of 20 mm to 45 mm.

3. The apparatus according to claim 1, further comprising a plurality of first through-holes extending from the first surface to the groove.

4. The apparatus according to claim 1, wherein the plurality of first through-holes are arranged at an outer-most dimension of the groove.

5. The apparatus according to claim 1, wherein the plurality of first through-holes is fluidly coupled to the groove.

6. The apparatus according to claim 1, wherein the groove is angled upwards toward the first surface.

7. The apparatus according to claim 1, wherein the protrusion comprises a downward-facing, horizontal surface.

8. The apparatus according to claim 1, wherein the first diameter is in the range of 417 mm to 370 mm and the second diameter is in the range of 400 mm to 450 mm.

9. An apparatus, comprising:
a gas distribution plate comprising an inlet plenum and an exhaust plenum; and
a showerhead plate comprising:
a first surface in direct contact with the gas distribution plate and an opposing second surface;
a circular cutout in the second surface, wherein the cutout comprises an opening having a first diameter at the second surface and a groove that projects radially outwards from a vertical axis and forms a second diameter, wherein the second diameter is larger than the first diameter;
a circular protrusion disposed between the first and second surfaces that projects inwards toward the axis, wherein the protrusion forms the groove;
a plurality of first through-holes extending from the first surface to the groove and in fluid communication with the exhaust plenum; and
a plurality of second through-holes extending from the first surface to a surface of the cutout and in fluid communication with the inlet plenum.

10. The apparatus according to claim 9, wherein the groove is angled upwards toward the first surface.

11. The apparatus according to claim 9, wherein the plurality of first through-holes are arranged at an outer-most dimension of the groove.

12. The apparatus according to claim 9, wherein the groove comprises a depth in a range of 20 mm to 45 mm.

13. The apparatus according to claim 9, wherein the protrusion comprises a downward-facing, horizontal surface configured to make contact with a susceptor.

14. The apparatus according to claim 9, wherein the first diameter is in the range of 417 mm to 370 mm.

15. The apparatus according to claim 9, wherein the second diameter is in the range of 400 mm to 450 mm.

16. The apparatus according to claim 9, further comprising a susceptor configured to engage with the opening of the cutout and the protrusion.

17. An apparatus, comprising:
a first horizontal surface and an opposing second horizonal surface;
a circular cutout in the second surface, wherein the cutout comprises an opening having a first diameter at the second surface and a groove that projects radially outwards from a vertical axis and forms a second diameter, wherein the second diameter is larger than the first diameter;
a circular protrusion disposed between the first and second surfaces that projects inwards toward the axis, wherein the protrusion forms the groove;
a plurality of first through-holes extending from the first surface to a surface of the groove, wherein the plurality of through-holes are fluidly coupled to the groove; and
a plurality of second through-holes extending from the first surface to a surface of the cutout and fluidly coupled to the cutout.

18. The apparatus according to claim 17, wherein the first diameter is in the range of 417 mm to 370 mm and the groove comprises a depth in a range of 20 mm to 45 mm.

19. The apparatus according to claim 17, wherein the second diameter is in the range of 400 mm to 450 mm and the groove comprises a depth in a range of 20 mm to 45 mm.

20. The apparatus according to claim 17, wherein the groove is angled upwards toward the first surface.
